(19) United States
(12) Patent Application Publication
(10) Pub. No.: US 2010/0312414 A1
(43) Pub. Date: Dec. 9, 2010

(54) SYSTEM AND METHOD FOR POWER MANAGEMENT AND LOAD SHEDDING

(76) Inventor: Balesh Kumar, Singapore (SG)

Correspondence Address: JONES, TULLAR & COOPER, P.C., P.O. BOX 2266 EADS STATION, ARLINGTON, VA, 22202, US

(21) Appl. No.: 12/734,957

(22) PCT Filed: Dec. 6, 2007
(86) PCT No.: PCT/SG2007/000424

§ 371 Date: Aug. 19, 2010

(51) Int. Cl. G01R 11/00

(52) U.S. Cl. 700/295

(57) ABSTRACT

A power management and load shedding method and system comprises the steps of:
a) Calculating a reserve power, RP as:

RP=AP_{T}−APₕ−GP_{T}
where AP_{T} is a total generation capacity of a plurality of running generators in a power system, APₕ is a highest capacity of any one of the running generators, and GP_{T} is a total current generated power from the running generators;
b) if the reserve power, RP, is negative, generating a load shedding list identifying one or more loads of the power system to be shed substantially simultaneously, such that a total power consumption of the loads in the load shedding list is equal to or greater than a deficit in the reserve power, RP;
c) storing the load shedding list in a buffer;
substantially continuously repeating steps a) to c); and
shedding the loads identified in the load shedding list stored in the buffer on detection of a failure of any one of the generators.

### CROSS-REFERENCE TO RELATED APPLICATIONS

This application is the U.S. National Phase, under 35 U.S.C. 371, of PCT/SG 2007/000424, filed Dec. 6, 2007, and published as WO 2009/072985 A1 on Jun. 11, 2009, the disclosures of which are expressly incorporated herein by reference.

### FIELD OF INVENTION

The present invention relates broadly to a power management and load shedding method and system.

### BACKGROUND

In power management systems, there is a need to maintain stability in the system. Power consumption and production must balance at all times as any significant imbalance could cause instability or severe voltage fluctuations within the power system and lead to failures. The process of stabilising the system is usually achieved through load shedding. Load shedding refers to the reduction of load in response to generation deficiency conditions caused by unexpected system disturbances. Examples of these disturbances could be in the form of lightning strikes, loss of generation, switching surges, faults etc.

Programmable Logic Controllers (PLCs) for automated load shedding have been used over recent years. A conventional PLC-based power management and load shedding system monitors the network status through various inputs such as the status of CT (Current Transformer), PT (Potential Transformer), and various transducer signals. The monitor is able to detect a system disturbance in the event (or combination of), under-frequency, under-voltage or over-current. Load shedding may then be necessary to keep the system operational. This is achieved by means of a separate hard-wired system that is able to reduce the overall load on the system by tripping the circuit breaker connected to a particular load. The PLC is programmed to shed a preset sequence of loads until the under-frequency situation is alleviated. The drawback of this system is that the PLC executes the load shedding sequentially based on a pre-defined load priority table. In other words, loads are shed in a preset sequence until the frequency returns to a normal condition. The process is independent of dynamic changes in the system loading, generation, or operating condition and this could result in insufficient and excessive load shedding. Also, the nature of the sequential shedding results in slow response times to disturbances.

“An Intelligent Load Shedding System” (Shokooh et al.) discloses a load shedding system which uses real time data acquired from the power system and produces optimum solution by recognizing different system patterns to detect system response. Central to the system is a dynamic knowledge base, which has been “trained” to react in accordance to known “disturbances”. This system is able to resolve the earlier problem of slow response times to disturbances. This is achieved through a “trained” list of load shedding tables which is stored in the system. Each load shedding table is an array of loads to be shed should a particular disturbance occur. When a particular disturbance occurs, the loads in the table are instantly shed in parallel (rather than in sequence), resulting in a much quicker, more precise load shedding operation.

Shokooh's system also has the capability of adaptive self-learning and automatic training of system knowledge base due to system changes. This self-learning and automatic training of the knowledge base requires expensive computation engine in the form of server computers. While this may be economically viable for large industrial systems, it is not as viable for smaller systems such as at an offshore platform or an FPSO (Floating Production, Storage and Offloading vessel) power stations that are typically much smaller and more temporary in nature.

Offshore platform or FPSO power systems have different characteristics to a large inter-connected system. The majority of offshore platform or FPSO electrical power systems comprise of two to three generators in the range of 6 MW˜16 MW to supply power. These are isolated systems and vulnerable to collapse in the event of machine outages or major disturbances. The power management and load shedding system for these offshore platforms or FPSO systems should be capable of adapting to changes in the load pattern to suit priority of production and limitation on generation units along with expansion of oil fields. Another challenge is that it should be cost effective due to the limited and shorter life spans of small and marginal oil fields.

A need therefore exists to provide a method and system for power management and load shedding that seeks to address at least one of the abovementioned problems.

### SUMMARY

In accordance with a first aspect of the present invention there is provide a power management and load shedding method comprising the steps of a) Calculating a reserve power, RP as:

RP=AP_{T}−APₕ−GP_{T}

where AP_{T} is a total generation capacity of a plurality of running generators in a power system, APₕ is a highest capacity of any one of the running generators, and GP_{T} is a total current generated power from the running generators;

b) if the reserve power, RP, is negative, generating a load shedding list identifying one or more loads of the power system to be shed substantially simultaneously, such that a total power consumption of the loads in the load shedding list is equal to or greater than a deficit in the reserve power, RP;

c) storing the load shedding list in a buffer;

substantially continuously repeating steps a) to c); and

shedding the loads identified in the load shedding list stored in the buffer on detection of a failure of any one of the generators.

The method may further comprise the step of determining GP_{T} by measuring power consumption and other parameters at respective generators, loads, or both of the power system.

GP_{T} may be measured using respective digital relays connected at the respective generators, loads, or both.

The failure of any one of the generators may be detected based on data obtained from the digital relays connected at the respective generators, loads, or both.

Electrical power system metered parameters and status parameters may be transmitted from the digital relays to the PLC via a communication link.

The PLC may perform steps a) to c) based on data obtained from the digital relays via the communication link.

The PLC may further be connected to circuit breakers at the respective loads via hard-wired connections for effecting the load shedding based on the load shedding list stored in the buffer on detection of the failure of any one of the generators.

The PLC may generate the load shedding list further based on a user defined priority assignment provided via an HMI coupled to the PLC.

In accordance with a second aspect of the present invention there is provide a power management and load shedding system comprising a plurality of digital relays connected at respective generators and loads of a power system; a PLC connected to the digital relays via a communication link, the PLC substantially continuously obtaining data from the relays for calculating a reserve power, RP as RP=AP_{T}−APₕ−GP_{T}, where AP_{T} is a total generation capacity of a plurality of running generators in a power system, APₕ is a highest capacity of any one of the running generators, and GP_{T} is the total current generated power from the running generators, and, if the reserve power, RP, is negative, generating a load shedding list identifying one or more loads of the power system to be shed substantially simultaneously, such that a total power consumption of the loads in the load shedding list is equal to or greater than a deficit in the reserve power, RP; and a buffer for storing the load shedding list; wherein the PLC is further connected to circuit breakers at the respective loads for shedding the loads identified in the load shedding list stored in the buffer on detection of a failure of any one of the generators.

The PLC may detect failure of any one of the generators based on data obtained from the digital relays connected at the respective loads, generators, or both.

The system may further comprise an HMI coupled to the PLC for user defining a priority assignment for the generating of the load shedding list.

The connection between the PLC and the circuit breakers may be hard-wired.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 illustrates an example embodiment of the power management and load shedding system.

FIG. 2 illustrates a schematic representation of the connections between a digital relay and a circuit breaker in an example embodiment

FIG. 3 illustrates an example embodiment of the Programmable Logic Circuit to perform the power management and load shedding function.

FIG. 4 shows a flowchart illustrating a power management and load shedding method according to an example embodiment.

### DETAILED DESCRIPTION

An example embodiment of the present invention discloses a system for power management and load shedding at an offshore platform or an FPSO. The system exploits the capability of modern digital relays to provide status and metered parameters of each major load and generator. Through modbus communication, the information is retrieved from digital relays and delivered to a specially developed Programmable Logic Circuit (PLC). This PLC provides two functions associated with Power Management Systems (PMS), namely system monitoring and shed list generation. The PLC may also display the information through a shared HMI (Human Machine Interface) for process control. At the HMI, information for each major load and generator may be displayed in the form of a network graphic with parameter thresholds. Whenever necessary, users may control the loads and generators through the HMI and manually override any automated load shedding sequences or enter and edit load priorities.

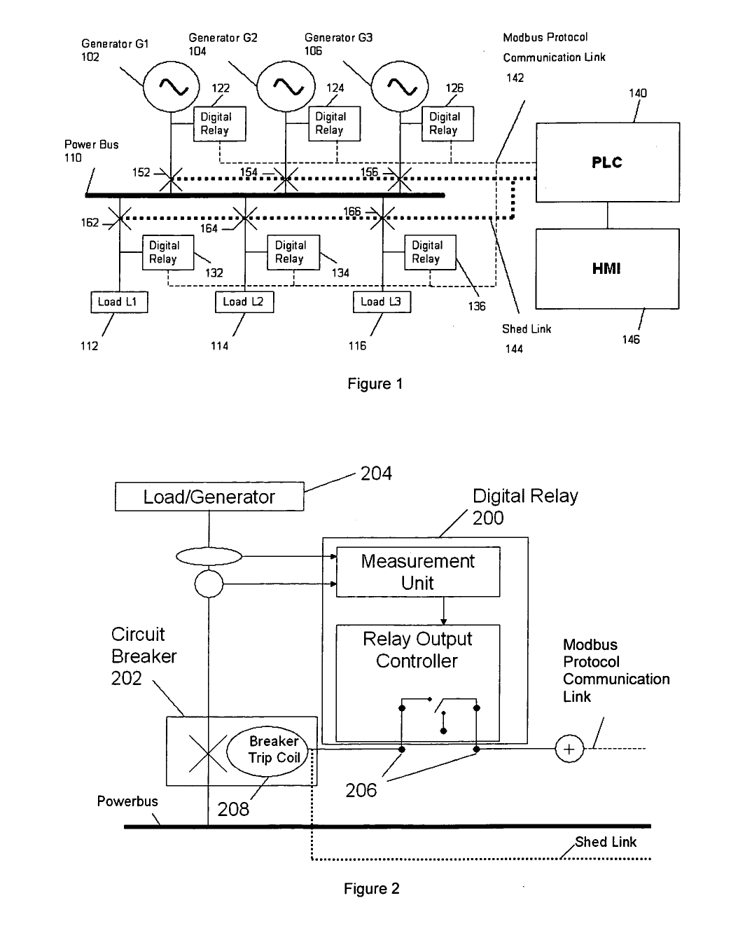

An example embodiment of the present invention is illustrated in FIG. 1. In FIG. 1, a power system 100 comprising three generators 102, 104, 106 and three loads 112, 114, 116, each of which protected by digital relays 122, 124, 126, 132, 134, 136 connected together via a power bus 110. In other example embodiments and/or implementations, any number of loads or generators may also be connected in similar configurations. The digital relays 122, 124, 126, 132, 134, 136 also meter information on the electrical power system network and transmit the relevant data to the PLC 140 via a modbus protocol communication link 142. Examples of the information metered by the digital relays 122, 124, 126, 132, 134, 136 are parameters such as voltage, current, frequency, power factor, active and reactive power, breaker status (On/Off/Faulty/Available), earth switch closed and control supply health. The PLC 140 is connected to a Human Machine Interface (HMI) 146 for display and user control. The generators 102, 104, 106 and loads 112, 114, 116 are also further protected by circuit breakers 152, 154, 156, 162, 164, 166. These circuit breakers 152, 154, 156, 162, 164, 166 are also controlled by the PLC 140 via a separate hard-wired shed link 144. The PLC 140 generates command signals that will trigger the respective breaker trip coil to trip the circuit breakers 152, 154, 156, 162, 164, 166. Within the hard-wired shed link 144, a plurality of individual hard-wired connections are made between each of the circuit breakers 152, 154, 156, 162, 164, 166, and the PLC 140 to facilitate fast tripping for load shedding in the example embodiment.

The digital relays 122, 124, 126, 132, 134, 136 in the example embodiment have metering and status capabilities as mentioned above. The digital relays 122, 124, 126, 132, 134, 136 are able to perform measurement of a host of parameters associated to the power system 100. Further calculations of these parameters can provide further, derived parameters. Examples of these measured and derived parameters are: phase current, residual current, demand and peak demand currents, voltage and frequency, active and reactive power, peak demand powers, energy and temperature.

Through these parameters, the digital relays 122, 124, 126, 132, 134, 136 are able to automatically provide numerous protection functions, as will be appreciated by a person skilled in the art. Examples include protection for over current, ground fault, thermal over load, locked rotor, field failure, under-voltage, over-voltage and under frequency conditions. The digital relays 122, 124, 126, 132, 134, 136 will monitor the respective generator, load and power bus to detect e.g. over current, ground fault, under-voltage, over-voltage or under-frequency conditions and activate the circuit breakers 152, 154, 156, 162, 164, 166 upon detection of such conditions.

FIG. 2 shows a schematic representation of the connections between a digital relay 200 and a circuit breaker 202 in an example embodiment. If a load or generator 204 experiences an abnormality in any or a combination of the protection parameters, the respective digital relays 200 immediately compares it with the predefined set value. Should the parameter exceed the set values, the relay 200 will change the status of the relay output contacts 206 which are wired to the respective tripping coil 208 of the circuit breaker 202. The tripping coil 208 gets energized and circuit breaker 202 operates to open the abnormal load or generator 204.

Through the activation of the circuit breakers 152, 154, 156, 162, 164, 166 (FIG. 1), the associated load or generator is disconnected from the power bus, to isolate a potential failing component and/or prevent cascading of the failure either to or from the isolated component.

As discussed earlier, in FIG. 1, the digital relays 122, 124, 126, 132, 134, 136 also possess metering capabilities as well as the capability of being connected together into a local area network (LAN). Typically, such LAN interconnection of digital relays is used for supervision functions for facilitating the installation and maintenance of a relay network. It is generally used to connect a set of relays using typically a manufacturer provided software platform on a centralized supervision system or a remote terminal unit. The relays may also remotely receive signals from the supervision system to set their operation parameters.

Embodiments of the present invention exploit the metering and networking capabilities of the digital relays 122, 124, 126, 132, 134, 136 for power management and load shedding in the power system 100.

In the example embodiment, an S-LAN is formed with the relays 122, 124, 126, 132, 134, 136 being interconnected via the existing modbus interfaces provided on the relays 122, 124, 126, 132, 134, 136 to the PLC 140 for implementing power management and load shedding. The PLC 140 in the example embodiment polls the individual relays 122, 124, 126, 132, 134, 136 in sequence for data such as phase current, residual current, demand and peak demand currents, voltage and frequency, power, peak demand powers, energy and temperature. The polled data allows the PLC 140 to detect generator failures and trigger load shedding. After the PLC 140 has polled each of the individual relays 122, 124, 126, 132, 134, 136 for data, the polling sequence repeats itself, allowing real-time updated data to be made available to the PLC 140 for further processing.

The digital relays 122, 124, 126, 132, 134, 136 in the example embodiment, possesses the capability to utilize modbus RTU (Return to Unit) protocol which permits the digital relays 122, 124, 126, 132, 134, 136 to read or write data by means of their addresses in modbus virtual address space. In simple terms, modbus RTU is a method of sending data between electronic devices. The device requesting data is known as the modbus master, while the devices supplying data are known as modbus slaves. In the example embodiment, the modbus master will be the PLC 140 and the modbus slaves will be the digital relays 122, 124, 126, 132, 134, 136. The digital relays 122, 124, 126, 132, 134, 136, keep all the status and metered parameters in a memory map. A configuration tool is used to define this map and respective communication boards of the digital relays 122, 124, 126, 132, 134, 136 and the PLC 140 are used to transmit data in binary bits. Each bit is sent as a voltage level with “zeroes” sent as a positive voltage and “ones” sent as a negative voltage. These bits are sent with a typical transmission baud rate of 9600 bits per second in the example embodiment. Each digital relay connected on the LAN in the example embodiment is preferably configured to have similar data transmission speed (baud rate), parity, data bits, and stop bit.

The modbus map comprises a list with characteristics that define:
What the data is (Current, Voltage, Power factor, Active power, etc.)
Where the data is stored (Data address)
How the data is stored (data type/length, member length, scale factor, byte)

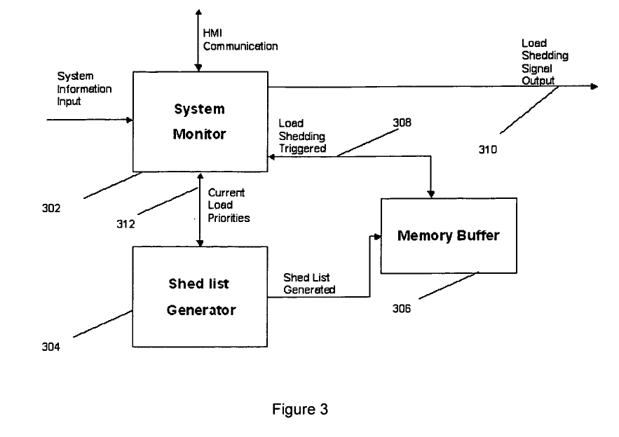

A schematic functional diagram of the PLC 140 in the example embodiment is illustrated in FIG. 3. The PLC 140 comprises a system monitor 302, a shed list generator 304 and a memory buffer 306. The system-monitoring unit 302 monitors the system for specific events such as generation failures. This may be done through various known techniques such as under voltage, under frequency, etc. Should an event such as a generation failure be detected, the system monitor unit 302 triggers the process to shed loads. For example, should a running generator be tripped, a trigger 308 to shed loads is activated immediately. This trigger 308 is sent to the buffer memory 306 which stores the list of loads to be shed upon triggering. The result is an output signal 310 to activate the circuit breakers 162, 164 or 166 (FIG. 1) of the loads that are to be shed. This output signal is transmitted via the separate hard-wired shed link 144 (FIG. 1).

In addition to event detection, the system monitor 302 also serves a function of priority determination in the example embodiment. Based on the current system status, the system monitor 302 selects the pre-determined load priorities to be fed into the shed list generation unit 304. For example, in the scenario where three generators are running, load priorities may be different from a scenario where two generators are running. In the example embodiment, the system monitor is made aware of the number of generators that are currently running and hence provide the shed list generation unit with the correct, pre-determined, load set and associated priorities 312.

The system monitor 302 may also transmit information on the current power system to the HMI 146 (FIG. 1) for display to the user. The user may then use this information and decide to change certain parameters or thresholds such as the pre-determined load priorities or parameters which cause the event triggers for load shedding.

When a trigger 308 to shed load is activated, the list of loads to be shed is read from the memory buffer 306. An output signal 310 to cause the circuit breakers of all the loads on the list read from the buffer memory 306 to trip is generated, for load shedding. For example if Load 112 (FIG. 1) is earmarked for shedding by the buffer memory 306, the output signal 310 will activate circuit breaker 162 (FIG. 1), thereby disconnecting the load 112 (FIG. 1) from the power system.

In the example embodiment, the decision on which loads to shed is solely determined by the shed list stored in the memory buffer 306. This list is continuously updated in real-time by the shed list generator 304. The shed list generator 304 obtains the necessary parameters and information for shed list generation from the system monitor 302, and continuously provides an updated shed list that is up-to-date with the changes in the power system.

To achieve shed list generation in the example embodiment, a reserve power is first computed. The reserve power is the power in reserve should a single running power generator suffer failure, and may be computed by the following equation:

RP=AP_{T}−APₕ−GP_{T} (E1)

Where
RP, Reserve power
AP_{T}, Total running generation capacity
APₕ, Highest capacity of a running generator
GP_{T}, Total current generated power (Real Time)

The total current generated power, GP_{T}, is measured by the digital relays 122, 124, 126 (FIG. 1) connected to the generators 102, 104, 106 (FIG. 1). It has been exploited by the inventors that the total current power consumption is equivalent to the total current generated power, GP_{T}. In example embodiments, the number of generators is typically fewer than the number of loads, and thus it is advantageous to measure total current generated power, GP_{T}, instead of e.g. measuring the actual consumption at each of the loads, which are more numerous in typical real systems. It is understood, however, that total current generated power GP_{T}, may be readily replaced by the total current consumption at the loads.

Next, the list of loads to be shed in the event of power generation failure is generated and stored in the memory buffer 306 in the example embodiment. If the computed reserve power is positive, sufficient power is available should a running power generator suffer failure and the memory buffer will not store any loads to be shed. Conversely, a negative reserve power implies a power shortage should generator failure occur. Thus, load shedding would be required to insure against power generator failure. As described earlier in the system monitor unit 302, the loads to be shed are selected from a set pre-determined by the user. In the example embodiment, this set comprises non-critical loads and is further prioritised in order of importance. The loads from the set and their associated priorities can be reconfigured on line through the HMI 146 (FIG. 1) to suit priority of production without disturbing production or other more critical functions.

The list of loads is populated, in order of priority, until the list contains enough loads to be shed such that the total power consumption of the shed loads is greater than or equal to the deficit in the computed reserve power. The equation representing this criterion can be expressed as:

RP+ΣLᵢ≧0, i=1,2 . . . n (E2)

where, Lᵢ represents the power consumption of the individual running loads that have been identified for shedding

In the example embodiment, when any loaded generator (112, 114 or 116 of FIG. 1) is tripped, all the loads from the current list in the memory buffer 306 will be shed substantially simultaneously. This will automatically stabilize the electrical power generation system in the example embodiment. Hence, in the event of partial loss of power generation, the operator may be able to maximize the production with the available power. Further, the example embodiment may prevent cascade failures or complete blackouts.

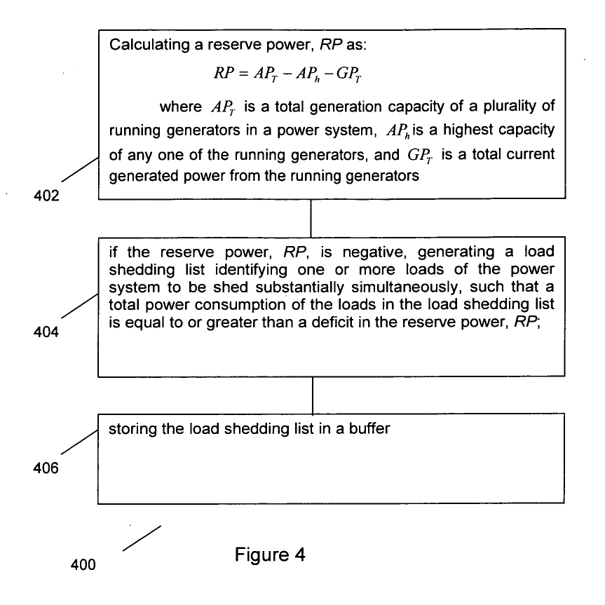

FIG. 4 shows a flowchart 400 illustrating a power management and load shedding method according to an example embodiment. At step 402, a reserve power, RP is calculated as:

RP=AP_{T}−APₕ−GP_{T}

where AP_{T} is a total generation capacity of a plurality of running generators in a power system, APₕ is a highest capacity of any one of the running generators, and GP_{T} is a total current generated power from the running generators. At step 404, if the reserve power, RP, is negative, a load shedding list identifying one or more loads of the power system to be shed substantially simultaneously is generated, such that a total power consumption of the loads in the load shedding list is equal to or greater than a deficit in the reserve power, RP. At step 406, the load shedding list is stored in a buffer. Steps 402 to 406 are substantially continuously repeating, and the loads identified in the load shedding list stored in the buffer are shedded on detection of a failure of any one of the generators.

The power management and load shedding system of the example embodiment enables the design engineers and operators to use the capabilities of microprocessor and communication technology for monitoring status, control, real time measurements, logical management of generated power for maximizing production, minimizing the downtime and trouble shooting of the electrical power system.

The typical offshore or FPSO electrical power system is small in size and generally isolated. Conventional PMS systems are designed for dedicated and large interconnected systems like power utilities. The response times of these conventional PMS systems are typically longer than for embodiments of the present invention. Embodiments of the present invention utilise a memory buffer which stores a list of loads to be shed should a generator fault occur. Thus, a simple look-up operation only is required, instead of more time consuming processing in existing systems. Furthermore, through the dedicated hard-wired shed link, the example embodiments are able to provide a quicker shedding response time compared to conventional PMS systems. This is because, conventional PMS systems do not utilise a dedicated hard-wired shed link for load shedding, rather, they typically utilise slower modbus communication links to achieve the load shedding of particular loads. Further, there may be likely issues of over or under shedding with conventional PMS systems. The example embodiments with a buffered shedding table updated in real time can effectively control load shedding and ensure a safe, reliable and quality power supply on a system such as offshore platforms or FPSO power systems.

The example embodiment of the present embodiment provides a simple, fast, real-time monitored power management and load shedding system specifically designed for small power system such as an offshore platform or an FPSO electrical power system. It is also highly cost-effective compared to more complex systems similar to the one disclosed by Shokooh et al.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

What is claimed is:

1-12. (canceled)

13. A power management and load shedding method comprising the steps of:
a) calculating a reserve power, RP as:
RP=AP_{T}−APₕ−GP_{T}
where AP_{T} is a total generation capacity of a plurality of running generators in a power system, APₕ is a highest capacity of any one of the running generators, and GP_{T} is a total current generated power from the running generators;
b) if the reserve power, RP, is negative, generating a load shedding list identifying one or more loads of the power system to be shed substantially simultaneously, such that a total power consumption of the loads in the load shedding list is equal to or greater than a deficit in the reserve power, RP;
c) storing the load shedding list in a buffer;
substantially continuously repeating steps a) to c); and
shedding the loads identified in the load shedding list stored in the buffer on detection of a failure of any one of the generators.

14. The method as claimed in claim 13, further comprising the step of determining GP_{T} by measuring power consumption and other parameters at respective generators, loads, or both of the power system.

15. The method as claimed in claim 14, wherein GP_{T} is measured using respective digital relays connected at the respective generators, loads, or both.

16. The method as claimed in claim 14, wherein the failure of any one of the generators is detected based on data obtained from the digital relays connected at the respective generators, loads, or both.

17. The method as claimed in claim 16, wherein electrical power system metered parameters and status parameters are transmitted from the digital relays to the PLC via a communication link.

18. The method as claimed in claim 17, wherein the PLC performs steps a) to c) based on data obtained from the digital relays via the communication link.

19. The method as claimed in claim 18, wherein the PLC is further connected to circuit breakers at the respective loads via hard-wired connections for effecting the load shedding based on the load shedding list stored in the buffer on detection of the failure of any one of the generators.

20. The method as claimed in claim 18, wherein the PLC generates the load shedding list further based on a user defined priority assignment provided via an HMI coupled to the PLC.

21. A power management and load shedding system comprising:
a plurality of digital relays connected at respective generators and loads of a power system;
a PLC connected to the digital relays via a communication link, the PLC substantially continuously obtaining data from the relays for calculating a reserve power, RP as RP=AP_{T}−APₕ−GP_{T}, where AP_{T} is a total generation capacity of a plurality of running generators in a power system, APₕ is a highest capacity of any one of the running generators, and GP_{T} is the total current generated power from the running generators, and, if the reserve power, RP, is negative, generating a load shedding list identifying one or more loads of the power system to be shed substantially simultaneously, such that a total power consumption of the loads in the load shedding list is equal to or greater than a deficit in the reserve power, RP; and
a buffer for storing the load shedding list;
wherein the PLC is further connected to circuit breakers at the respective loads for shedding the loads identified in the load shedding list stored in the buffer on detection of a failure of any one of the generators.

22. The system as claimed in claim 21, wherein the PLC detects failure of any one of the generators based on data obtained from the digital relays connected at the respective loads, generators, or both.

23. The system as claimed in claim 21, further comprising an HMI coupled to the PLC for user defining a priority assignment for the generating of the load shedding list.

24. The system as claimed in claim 21, wherein the connection between the PLC and the circuit breakers is hard-wired.
